(19) United States
(12) Patent Application Publication
(10) Pub. No.: US 2014/0086422 A1
(43) Pub. Date: Mar. 27, 2014

(54) ELECTRONIC DEVICE, SYSTEM AND METHOD FOR MANAGING SOUND EFFECT

(71) Applicant: Hon Hai Precision Industry Co., Ltd., New Taipei (TW)

(72) Inventor: TAI-WEI HUANG, New Taipei (TW)

(73) Assignee: Hon Hai Precision Industry Co., Ltd., New Taipei (TW)

(21) Appl. No.: 14/014,487

(22) Filed: Aug. 30, 2013

(30) Foreign Application Priority Data
Sep. 21, 2012 (TW) 101134811

(51) Int. Cl. H03G 3/20

(52) U.S. Cl. CPC H03G 3/20
USPC 381/57

(57) ABSTRACT

A sound effect managing method is executed by an electronic device. In the method audio signals are generated and ambient noises are collected. Then audio data are obtained from the collected ambient noise. The audio data of the ambient noise are set as reference audio data and the reference audio data are adjusted by pre-set audio data to obtain target audio data. The audio signals are adjusted according to the target audio data and producing the adjusting audio signals.

### BACKGROUND

1. Technical Field

The disclosure relates to volume adjusting technologies, and particularly to an electronic device and method for auto adjusting a volume.

2. Description of Related Art

An electronic device, such as a mobile phone, can have different ringtones and play various music depending on a user's need. The volume of the electronic device is set by the user and will not be changed until the user re-sets the volume. However, ambient noise may affect the clarity of the audio from the electronic device. Thus, the user often adjusts the volume of the electronic device to hear the audio better. This is an inconvenience to users.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a functional block diagram of an electronic device in accordance with an embodiment, the electronic device including a sound effect managing system.

FIG. 2 is a functional block diagram of a sound effect managing system including a setting module.

FIG. 3 is a functional block diagram of the setting module of FIG. 2.

FIG. 4 shows a user interface provided by the setting module of FIG. 3.

FIG. 5 is a flowchart of a sound effect managing method in accordance with an embodiment.

### DETAILED DESCRIPTION

All of the processes described below may be embodied in, and fully automated via, functional code modules executed by one or more general purpose electronic devices or processors. The code modules may be stored in any type of non-transitory computer-readable medium or other storage device. Some or all of the methods may alternatively be embodied in specialized hardware. Depending on the embodiment, the non-transitory computer-readable medium may be a hard disk drive, a compact disc, a digital video disc, a tape drive or other suitable storage medium.

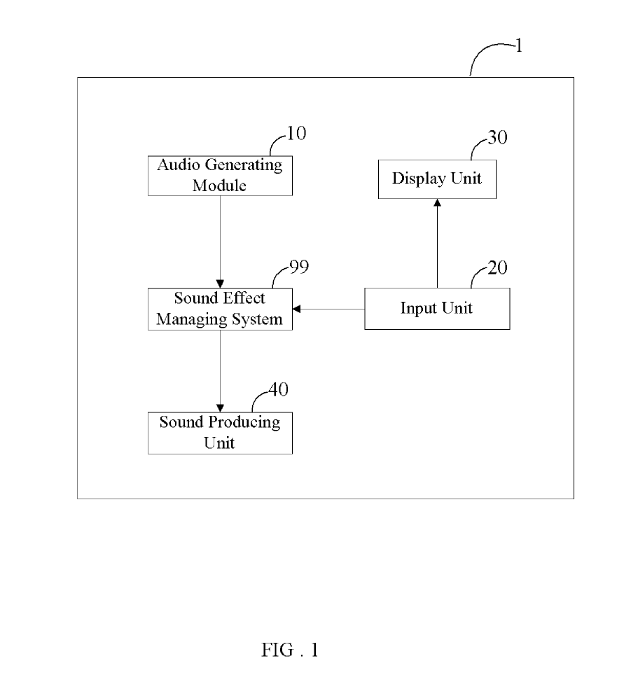

FIG. 1 shows function blocks of an electronic device 1 of an embodiment. The electronic device 1 may be, but is not limited to a mobile phone, a MP3 player, and a PDA. Taking a mobile phone as an example, the electronic device 1 includes an audio generating module 10, an input unit 20, a display unit 30, and a sound producing unit 40.

The audio generating module 10 includes a number of applications (not shown) executed to carry out various functions, including, but not limited to, a game playing function, a music playing function, a telephone function and generate audio signals synchronously.

The sound producing unit 40 converts the audio signal to sound waves and outputs the sound waves. In this embodiment, the sound producing unit 40 is a speaker.

The display unit 30 is a touch screen. The input unit 20 can be virtual buttons displayed on the display unit 30. In other embodiment, the input unit 20 can be physical buttons set in the electronic device 1.

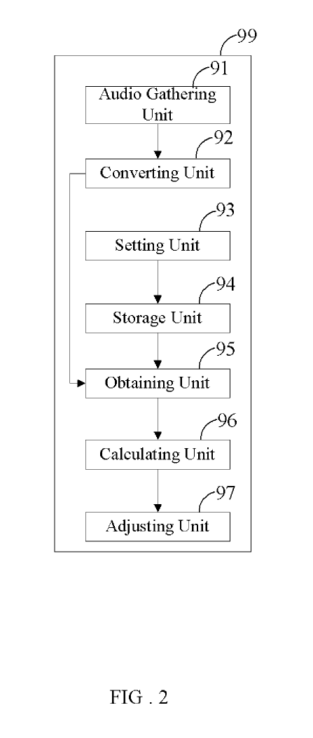

FIGS. 1 and 2 show that the electronic device 1 further includes a sound effect managing system 99 for auto adjusting the audio signals according to the ambient noise. In detail, the sound effect managing system 99 includes an audio gathering unit 91, a converting unit 92, a setting unit 93, a storage unit 94, an obtaining unit 95, a calculating unit 96, and an adjusting unit 97.

The audio gathering unit 91 collects all ambient noises at a predetermined time period, and generates electronic signals in response to the audio signal. The audio gathering unit 91 may be a microphone. The ambient noise can include the noise of construction and traffic for example.

The converting unit 92 converts electronic signals into digital audio signals.

The converting unit 92 may be an A/D convertor.

The setting module 93 pre-sets audio data for adjusting the audio signals in response to user commands inputted by input unit 20. In this embodiment, the audio data include volume levels and frequency levels.

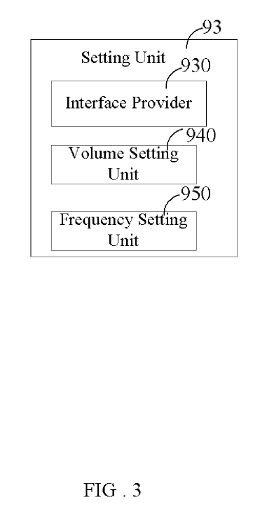

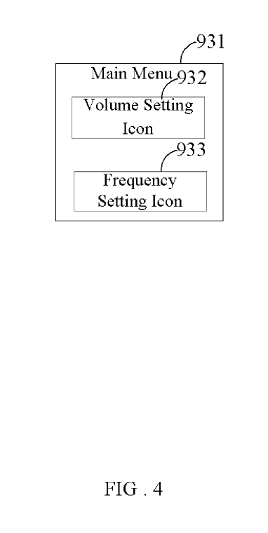

FIGS. 3-4 show that the setting module 93 includes an interface provider 930, a volume setting unit 940, and a frequency setting unit 950. The interface provider 930 provides a main menu 931 to display on the display unit 30 in response to the user commands. The main menu 931 includes a volume setting icon 932 and a frequency setting icon 933.

The interface provider 930 further provides a first submenu associated with the volume setting icon 932. The first submenu includes a number of volume levels. In other words, the volume setting icon 932 is associated with a number of the volume levels. The value of each volume levels may be set by the user. In this embodiment, each volume level increases or decreases the audio volume by 2 dB. For example, the volume levels may be −10,−8,−6,−4,−2,0,2,4,6,8,10. In detail, when volume setting icon 932 is clicked via the input unit 20, the interface provider 930 displays the volume levels on the display unit 30. When one of the volume levels is selected via the input unit 20, the volume setting unit 940 pre-sets the volume level at the selected volume level.

The interface provider 930 further provides a second submenu (not shown) associated with the frequency setting icon 933. The second submenu includes a number of frequency levels. In other words, the frequency setting icon 933 is associated with a number of frequency levels. In this embodiment, the value of each volume levels may be set by the user. Frequency level may be increased or decreased by 10%. For example, the frequency levels may be −20%,−10%,0,10%,20%. In detail, when the frequency setting icon 933 is clicked via the input unit 20, the interface provider 930 display the frequency of levels on the display unit 30. When one of the frequency levels is selected via the input unit 20, the frequency setting unit 950 pre-sets the frequency level at the selected frequency level.

The storage unit 94 stores the pre-set audio data, such as the volume levels, the frequency levels, the pre-set volume level, and the pre-set frequency level.

The obtaining unit 95 obtains audio data of the ambient noise and the pre-set audio data from the storage unit 94. In detail, the obtaining unit 95 obtains an audio volume and an audio frequency from the ambient noise, and obtains the pre-set volume level and the pre-set frequency level from the storage unit 94.

The calculating unit 96 sets the data of the ambient noise as reference audio data, and adjusts the reference audio data by the set audio data to generate target audio data. In detail, the reference audio data includes a reference volume and a reference audio frequency. The calculating unit 96 sets the audio volume of the ambient noise as the reference volume, and adjusts the reference volume by the pre-set volume level to obtain the target volume. The calculating unit 96 sets the frequency of the ambient noise as the reference frequency, and adjusts the reference frequency by the pre-set audio frequency to obtain a target frequency. For example, the audio volume and the audio frequency of the ambient noise are 50 dB and 1000 Hz, the pre-set volume level and the pre-set frequency level are 8 dB and −10%, The calculating unit 96 calculates the target volume and the target frequency to be 58 dB and 900 Hz.

The adjusting unit 97 adjusts the audio signal generated by the audio generating module 91 based on the target audio data. Therefore, the sound producing unit 40 outputs sound waves according to the target audio data. In other words, when the target volume and the target frequency are 58 dB and 900 Hz, the volume and the frequency of the sound waves output by the sound producing unit 40 are 58 dB and 900 Hz.

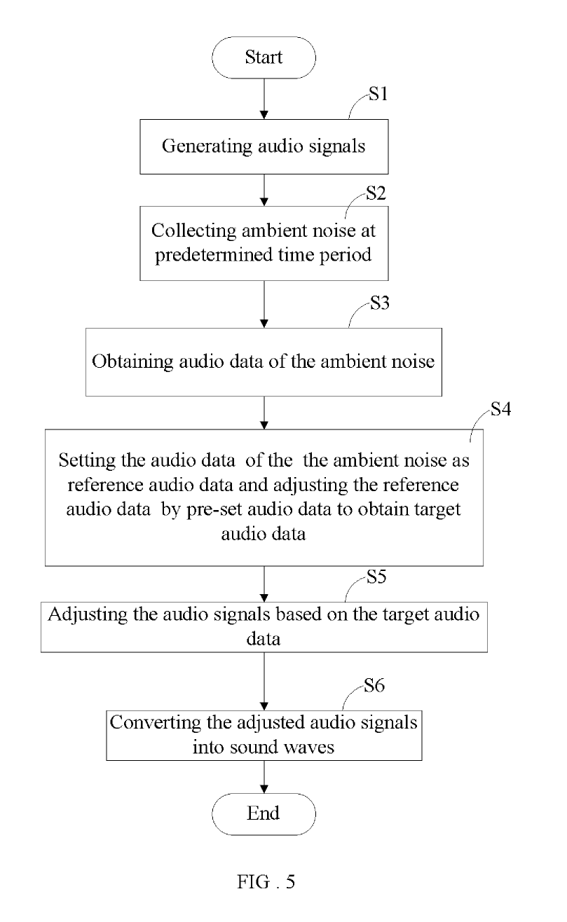

FIG. 5 shows a flowchart of a sound effect managing method. The sound effect managing method is applied to the electronic device 1. The sound effect managing method includes the following steps.

In step S1, the audio generating module 10 generates audio signals.

In step S2, the audio gathering unit 91 collects ambient noise.

In step S3, the obtaining unit 95 obtains audio data of the ambient noise and a set audio data from the storage unit 94. In detail, the audio data of the ambient noise include the volume and the frequency of the ambient noise. The set audio data includes a set volume level, and a set frequency level.

In step S4, the calculating unit 96 sets the audio data of the ambient noise as reference audio data, and adjusts the reference audio data by the set audio data to obtain target audio data. For example, the volume and the frequency of the ambient noise are 50 dB and 1000 Hz. The pre-set volume level and the pre-set frequency level are 8 dB and −10%. The target audio data are calculated to be 58 dB and 900 Hz.

In step S5, the adjust unit 96 adjusts audio data of the audio signals generated by the audio generating module 10 to the target audio data.

In step S6, the sound producing unit reproduces the adjusted audio signal into sound waves. For example, the target audio data are 58 dB and 900 Hz, the volume and the frequency of the sound waves generated by the sound producing unit 40 are 58 dB and 900 Hz too.

Even though relevant information and the advantages of the present embodiments have been set forth in the foregoing description, together with details of the functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. An electronic device comprising:
an audio generating module to generate audio signals;
a sound effect generating system comprising:
an audio gathering unit to collect ambient noise;
an obtaining unit to obtains audio data of the ambient noise and pre-set data;
a calculating unit to set the audio data of the ambient noise as reference audio data and adjust the reference audio data by pre-set audio data to obtain target audio data; and
an adjusting unit to adjust the audio signals based on the target audio data; and
a sound producing unit to convert the adjusted audio signal into sound waves.

2. The electronic device of claim 1, wherein the audio data of the ambient noise comprise a volume of the ambient noise, the pre-set audio data comprises a volume level.

3. The electronic device of claim 2, wherein the electronic device further comprises a setting module, the setting module comprises an audio setting unit to set volume level.

4. The electronic device of claim 1, wherein the audio data of the ambient noise comprise an audio frequency of the ambient noise, the pre-set audio data comprises a frequency level.

5. The electronic device of claim 4, wherein the electronic device further comprises a setting module, the setting module comprises an audio setting unit to set volume level.

6. A sound effect managing system, executed by an electronic device to managing a sound effect of the electronic device, the electronic device comprising an audio gathering unit to collect ambient noise; an audio generating module to generate audio signals, and a sound producing unit to convert the audio signals to sound waves, the sound effect managing system comprising:
an obtaining unit obtaining audio data of the ambient noise;
a calculating unit setting the audio data of the ambient noise as reference audio data and adjust the reference audio data by pre-set audio data to obtains target audio data; and
an adjusting unit adjusting the audio signals generated by the audio generating module based on the target audio data, and transmitting the adjusted audio signals to the sound producing unit to convert the adjusted audio signal into sound waves.

7. The sound effect managing system of claim 6, wherein the audio data of the ambient noise comprise a volume of the ambient noise, the pre-set audio data comprises a volume level.

8. The sound effect managing system of claim 6, wherein the audio data of the ambient noise comprise an audio frequency of the ambient noise, the pre-set audio data comprises a frequency level.

9. A sound effect managing method, executed by an electronic device, the sound effect managing method comprises:
generating audio signals;
collecting ambient noise;
obtaining audio data of the ambient noise;
setting the audio data of the ambient noise as reference audio data and adjusting the reference audio data by pre-set audio data to obtains target audio data;
adjusting the audio signals based on the target audio data; and
producing the adjusting audio signals.

10. The sound effect managing method of claim 9, wherein the audio data of the ambient noise comprise a volume of the ambient noise, the pre-set audio data comprises a volume level.

11. The sound effect managing method of claim 9, wherein the audio data of the ambient noise comprise an audio frequency of the ambient noise, the pre-set audio data comprises a frequency level.
